(19) United States
(12) Patent Application Publication
(10) Pub. No.: US 2017/0162600 A1
(43) Pub. Date: Jun. 8, 2017

(54) MANUFACTURING METHODS OF FLEXIBLE DISPLAY PANELS, FLEXIBLE GLASS SUBSTRATES, AND FLEXIBLE DISPLAY PANELS

(71) Applicant: Shenzhen China Star Optoelectronics Technology Co. Ltd., Shenzhen, Guangdong (CN)

(72) Inventor: Weijing ZENG, Shenzhen, Guangdong (CN)

(73) Assignee: Shenzhen China Star Optoelectronics Technology Co. Ltd., Shenzhen, Guangdong (CN)

(21) Appl. No.: 14/787,572

(22) PCT Filed: Aug. 25, 2015
(86) PCT No.: PCT/CN2015/088023

§ 371 Date: Oct. 28, 2015

(30) Foreign Application Priority Data
Aug. 3, 2015 (CN) 201510478923.2

(51) Int. Cl. H01L 27/12

(52) U.S. Cl. CPC H01L 27/1218; H01L 27/1262; H01L 51/0097

(57) ABSTRACT

A manufacturing method of flexible display panels, a flexible glass substrate, and a flexible display panel are disclosed. The manufacturing method of the flexible display panel includes: forming a TFT layer at one side of a flexible glass substrate; forming a polymer enhanced layer at the other side of the flexible glass substrate; curing the polymer enhanced layer; forming a display layer on the TFT layer; and forming an encapsulation layer on the side of the flexible glass substrate where the TFT layer is located. With such configuration, the compressive strength of the flexible glass substrate is enhanced so as to enhance the quality of products.

### BACKGROUND OF THE INVENTION

1. Field of the Invention

The present disclosure relates to liquid crystal display technology, and more particularly to a manufacturing method of flexible display panels, a flexible glass substrate, and a flexible display panel.

2. Discussion of the Related Art

Flexible display devices are also called as roll-up displays, which are display devices that may be arbitrarily bent and deformed and are made by flexible materials. The flexible displays may include e-paper, flexible liquid crystal devices, and Organic Light-Emitting Diode (OLED) displays, and are characterized by attributes such as light, small, thin, portable, anti-high and low temperature, anti-vibration, and may be well adapted to environment.

The OLED devices include the attributes such as self-luminescent, high brightness, wide viewing angle, high brightness, flexible and low power consumption, and are widely adopted by panels of cellular phones, computer, and televisions. The OLED display technology adopts very thin organic material emitting layer and flexible substrate. When current passes by, the organic material may emit lights. However, as the organic material may react with water and oxygen, water vapors and oxygen may damage the organic materials and the luminescent performance may be affected. Thus, flexible OLED displays are demanded to include good flexible and barrier property subject to the water and the oxygen.

Currently, the manufacturing method of flexible OLED devices may adopt the plastic substrate of polymer to form an organic film on the plastic substrate and to form a TFT and OLED device layer. In the end, the organic/inorganic materials are stacked to form a thin film package. However, most of the plastic substrate of polymer material are fragile to the high-temperature process. In addition, the requirement of forming the inorganic thin film having enough water-blocking capability increases the difficulty of the manufacturing process. Another solution is to adopt the flexible glass substrate. The flexible glass substrate owns a better surface characteristics and has excellent high temperature performance. In addition, the water-blocking capability of the flexible glass substrate is good, and thus the inorganic thin film is not needed, which simplifies the manufacturing process. However, the flexible glass substrate is fragile. Not only the quality of the product is affected, but also the yield rate and the application of the products are limited.

### SUMMARY

The object of the invention is to provide a manufacturing method of flexible display panels, a flexible glass substrate, and a flexible display panel to avoid the performance issue caused by the fragile flexible glass substrate.

In one aspect, a manufacturing method of flexible display panels includes: forming a TFT layer at one side of a flexible glass substrate; forming a polymer enhanced layer at the other side of the flexible glass substrate; curing the polymer enhanced layer; forming a display layer on the TFT layer; and forming an encapsulation layer on the side of the flexible glass substrate where the TFT layer is located.

Wherein the polymer enhanced layer is made by PET, PI, or epoxy resin.

Wherein the step of curing the polymer enhanced layer further comprises baking the polymer enhanced layer or radiating the polymer enhanced layer by UV rays.

Wherein the polymer enhanced layer is formed by at least one of spin-coating, sputtering, spray coating and screen printing.

Wherein the display layer is an OLED layer.

Wherein the OLED layer comprises an anode metal layer, an organic layer and a cathode metal layer, the OLED layer is formed by ink-jet printing or vacuum evaporation, and the OLED layer is formed by a surface film formation or a roll-to-roll process.

Wherein the encapsulation layer is formed by surface encapsulation or thin-film encapsulation.

In another aspect, a flexible glass substrate comprises a polymer enhanced layer arranged at one side of the flexible glass substrate.

Wherein the polymer enhanced layer is made by PET, PI, or epoxy resin.

In another aspect, a flexible display panel includes: a TFT layer, a display layer, an encapsulation layer and a flexible glass substrate; and wherein a polymer enhanced layer is formed at one side of the flexible glass substrate, and the TFT layer is arranged at the other side of the flexible glass substrate opposite to the polymer enhanced layer, the display layer is arranged on the TFT layer, and an encapsulation layer is arranged on the side of the flexible glass substrate where the TFT layer is located.

Wherein the polymer enhanced layer is made by PET, PI, or epoxy resin.

Wherein the display layer is an OLED layer.

Wherein the OLED layer comprises an anode metal layer, an organic layer and a cathode metal layer, the OLED layer is formed by ink-jet printing or vacuum evaporation, and the OLED layer is formed by a surface film formation or a roll-to-roll process.

In view of the above, the polymer enhanced layer at one side of the flexible glass substrate. As the polymer material owns the attributes such as strong flexibility, high compressive resistance, and high mechanical strength, these prevent the stress from being centralized so as to overcome the fragile issue of flexible glass substrate. In addition, the compressive strength of the flexible glass substrate is enhanced. As such, the attributes of the flexible glass including anti-high-temperature, good surface characteristics, and good water blocking capability are achieved. At the same time, the flexibility and high pressure resistance are obtained. Further, the encapsulation efficiency and the display performance of the flexible display panel are enhanced. Also, by configuring the polymer enhanced layer at one side of the flexible glass substrate, there are a variety of methods may be selected in the subsequent process.

### BRIEF DESCRIPTION OF THE DRAWINGS

FIG. 1 is a flowchart of the manufacturing method of the flexible display panels in accordance with a first embodiment.

FIG. 2 is a schematic view showing the manufacturing method of the flexible display panels in accordance with the first embodiment.

FIG. 3 is a flowchart of the manufacturing method of the flexible display panels in accordance with a second embodiment.

FIG. 4 is a schematic view showing the cross-section of the flexible glass substrate in accordance with one embodiment.

FIG. 4 is a schematic view showing the cross-section of the flexible display panel in accordance with one embodiment.

### DETAILED DESCRIPTION OF THE EMBODIMENTS

Embodiments of the invention will now be described more fully hereinafter with reference to the accompanying drawings, in which embodiments of the invention are shown.

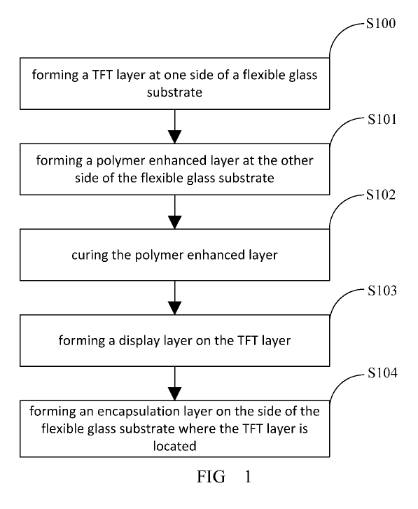

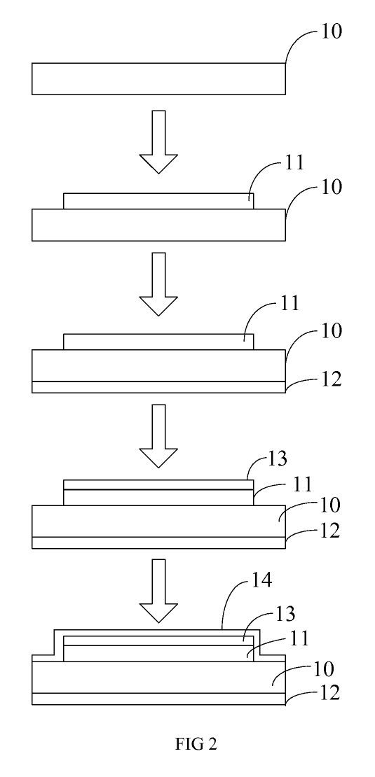

FIGS. 1 and 2 illustrate the manufacturing method of the flexible display panel in accordance with one embodiment. The method includes the following steps.

In block S100, a TFT layer 11 is formed at one side of the flexible glass substrate 10.

The flexible glass substrate 10 may be a thin and transparent glass, which may be bent easily by human. The thin film transistor (TFTs) are configured for driving liquid crystal pixels on the panel.

In block S101, a polymer enhanced layer 12 is formed at the other side of the flexible glass substrate 10.

The glass is a typical brittle material. Although the flexible glass may be bent, but the compression strength of the flexible glass is still low. Defects exist in the surface and the internal of the flexible glass, and crack may expand when being subject to external forces and environmental media.

The polymer materials own a certain flexibility and may be elastically deformed, which prevents the stress from being centralized. In addition, the polymer enhanced layer 12 may be easily adhere to glass, and owns the attributes such as high mechanical strength and high anti-pressure capability.

Thus, by forming the polymer enhanced layer 12 at one side of the flexible glass substrate 10, the polymer enhanced layer 12 may be adhered to the 10 may be adhered to the flexible glass substrate 10. In this way, the flexibility of the polymer may enhance the performance of the flexible glass by increasing the anti-pressure capability.

In the present disclosure, the TFT layer 11 is formed at one side of the flexible glass substrate 10, and the polymer enhanced layer 12 is formed at the other side of the flexible glass substrate 10. This prevents the polymer enhanced layer 12 from being damaged by the TFT high-temperature manufacturing process. In addition, as no high-temperature manufacturing process is needed in the following process, the glass substrate and the polymer layer are prevented from being detached from each other due to different coefficients of expansion.

For instance, the polymer enhanced layer 12 may be PET, PI, or epoxy resin. For instance, PET may be polyethylene terephthalate, which owns attributes such as great mechanical property, high impact strength, good folding resistance, anti-high and low temperature, and low penetration rate with respect to gas and vapors. That is, the PET owns great performance with respect to oxygen, water, oil, and smell. In addition, the transparency of PET is high, which may block ultraviolet rays. Thus, by adopting the PET to be the polymer enhanced layer 12, not only the anti-pressure capability of the flexible glass may be enhanced, but also the performance of the flexible glass substrate 10 subject to water, high and low temperature may also be enhanced. In addition, the transparency and gloss of the flexible glass are not affected. Polyimide (PI) owns the attributes such as anti-abrasion, anti-high-temperature, and high impact resistance. Epoxy resin owns good physical and chemical performance. For instance, epoxy resin owns great bonding strength toward metal or nonmetal. In addition, epoxy resin owns good flexibility. It can be understood that the polymer enhanced layer 12 may be other polymer materials having good flexibility, high adhesivity, and high compressive resistance.

The polymer enhanced layer 12 may be formed by one of the spin-coating, sputtering, spray coating and screen printing, wherein spin-coating is abbreviation of spinning and coating method. The spin-coating method includes batching, spinning at high speed, and forming the film by volatilization. The thickness of the formed film is controlled by configuring the time, speed, drops of liquid of the coating, and the concentration, the viscosity of the solution. Sputtering process is characterized by attributes such as the temperature of the substrate is low, the quality of the thin film is pure, the density of the tissue is uniform, robustness, and repeatability. The coating process may adopt spray guns or discs to coating the fog droplets, which are uniformly distributed by pressure or centrifugal forces, on the surface of the coated subject. The efficiency of such process is pretty high. Screen printing is characterized by attributes such as soft layout, small compression forces, and high covering power. In real manufacturing process, the polymer enhanced layer 12 may be formed by the method selected in accordance with the polymer material, the environment and conditions.

In block S102, the polymer enhanced layer 12 is cured.

The polymer enhanced layer 12 may be cured by, such as, backing or by radiation via UV rays. In the embodiment, the polymer enhanced layer 12 may be PET on the flexible glass substrate 10, and is cured by UV rays

In block S103, a display layer 13 is formed on the TFT layer 11.

In the embodiment, the display layer 13 is the OLED layer. In particular, the OLED layer may include an anode metal layer, an organic layer and a cathode metal layer. OLED may be formed by ink-jet printing or vacuum evaporation, and the OLED layer is formed on the TFT layer 11 by film formation. The ink-jet printer may include system controller, inkjet controller, spray nozzle, and driving mechanism of print substrate. The organic objects are ejected out, when being controlled by the inkjet controller, and then are printed on the print substrate. It can be understood the display layer 13 may be the corresponding display panel for the flexible display e-paper or flexible display panel.

In block S104, an encapsulation layer 14 is formed at one side of the flexible glass substrate 10 where the TFT layer 11 is located. As the blocking capability of the flexible glass substrate 10 subject to the water and oxygen is relatively low when being compared with the rigid glass substrate, the flexible glass substrate 10 has to be effectively encapsulated. In particular, the encapsulation layer 14 may be formed by surface encapsulation or thin-film encapsulation, wherein the thin-film encapsulation may include stacking the inorganic or organic materials. The packing material may be SiNx/SiOC/SiNx. The method is accomplished by depositing the thin film having the blocking capability with respect to water and oxygen when the temperature is low. Regarding the surface encapsulation, solid glue having high water-blocking capability is adhered to the encapsulation cover, and then is bonded with the substrate to accomplish the encapsulation.

In view of the above, the polymer enhanced layer at one side of the flexible glass substrate. As the polymer material owns the attributes such as strong flexibility, high compressive resistance, and high mechanical strength, these prevent the stress from being centralized so as to overcome the fragile issue of flexible glass substrate. In addition, the compressive strength of the flexible glass substrate is enhanced. As such, the attributes of the flexible glass including anti-high-temperature, good surface characteristics, and good water blocking capability are achieved. At the same time, the flexibility and high pressure resistance are obtained. Further, the encapsulation efficiency and the display performance of the flexible display panel are enhanced. Also, by configuring the polymer enhanced layer at one side of the flexible glass substrate, there are a variety of methods may be selected in the subsequent process.

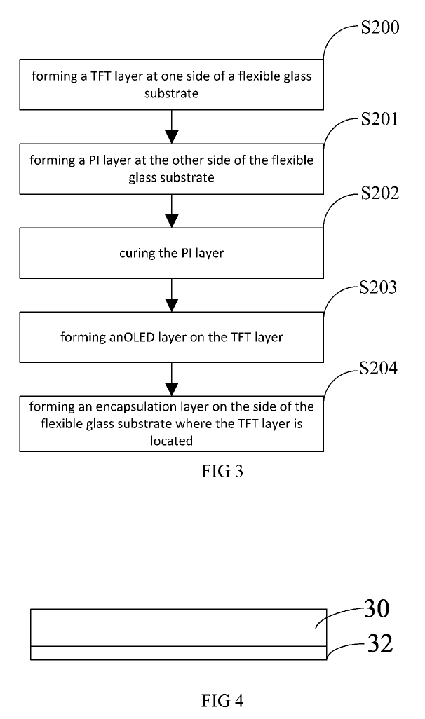

FIGS. 2 and 3 are flowcharts illustrating the manufacturing method of the flexible display panels in accordance with another embodiment. The method includes the following steps.

In block S200, a TFT layer 11 is formed at one side of the flexible glass substrate 10.

In block S201, a PI enhanced layer is formed at the other side of the flexible glass substrate. In particular, the PI enhanced layer is formed by sputtering.

In block S202, the PI enhanced layer is cured. In this step, the PI enhanced layer is cured by baking, including a pre-curing and a main-curing. The temperature of pre-curing step is in a range of 90 and 150 degrees. For instance, in an example, the temperature of pre-curing step is 100 degrees. The time period is in a range between one to four minutes. In an example, the time period may be 2 minutes. The temperature of main-curing step is in a range 200 and 270 degrees. For instance, in an example, the temperature of main-curing step is 230 degrees. The time period of the main-curing is in a range between 25 and 33 minutes. In an example, the time period of the main-curing may be 30 minutes.

In block S203, the OLED layer is formed on the TFT layer. In the embodiment, the OLED layer may be formed by vacuum evaporation, and may be formed by roll-to-roll process.

In block S204, an encapsulation layer is formed at one side of the flexible glass substrate where the TFT layer is located. In the embodiment, the encapsulation is formed by SiNx/SiOC/SiNx via the thin-film encapsulation.

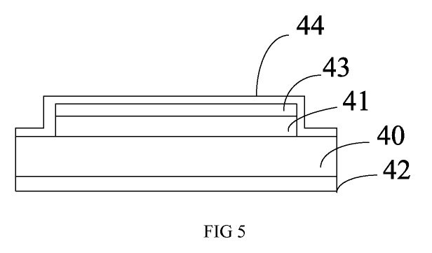

In one embodiment, a flexible glass substrate, as shown in FIG. 4, is provided. A polymer enhanced layer 32 is formed at one side of the flexible glass substrate 30.

Specifically, the polymer enhanced layer 32 may be PET, PI, or epoxy resin. The polymer enhanced layer 32 may be formed on the flexible glass substrate 30 by one of the spin-coating, sputtering, spray coating and screen printing.

In one embodiment, a flexible display panel, as shown in FIG. 5, includes a TFT layer 41, a display layer 43, an encapsulation layer 44 and a flexible glass substrate 40, wherein one side of the flexible glass substrate 40 includes a polymer enhanced layer 42.

The TFT layer 41 is arranged on one side of the flexible glass substrate 40 that is opposite to the side where the polymer enhanced layer 42 is located. The display layer 43 is arranged on the TFT layer 41. The encapsulation layer 44 is arranged at one side of the flexible glass substrate 40 where the TFT layer 41 is located.

Specifically, the polymer enhanced layer 42 may be PET, PI, or epoxy resin. The polymer enhanced layer 42 may be formed on the flexible glass substrate 40 by one of the spin-coating, sputtering, spray coating and screen printing. The display layer 43 may be the OLED layer.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A manufacturing method of flexible display panels, comprising:
forming a TFT layer at one side of a flexible glass substrate;
forming a polymer enhanced layer at the other side of the flexible glass substrate;
curing the polymer enhanced layer;
forming a display layer on the TFT layer; and
forming an encapsulation layer on the side of the flexible glass substrate where the TFT layer is located.

2. The method as claimed in claim 1, wherein the polymer enhanced layer is made by PET, PI, or epoxy resin.

3. The method as claimed in claim 2, wherein the step of curing the polymer enhanced layer further comprises baking the polymer enhanced layer or radiating the polymer enhanced layer by UV rays.

4. The method as claimed in claim 2, wherein the polymer enhanced layer is formed by at least one of spin-coating, sputtering, spray coating and screen printing.

5. The method as claimed in claim 4, wherein the display layer is an OLED layer.

6. The method as claimed in claim 5, wherein the OLED layer comprises an anode metal layer, an organic layer and a cathode metal layer, the OLED layer is formed by ink-jet printing or vacuum evaporation, and the OLED layer is formed by a surface film formation or a roll-to-roll process.

7. The method as claimed in claim 6, wherein the encapsulation layer is formed by surface encapsulation or thin-film encapsulation.

8. A flexible glass substrate comprises a polymer enhanced layer arranged at one side of the flexible glass substrate.

9. The flexible glass substrate as claimed in claim 8, wherein the polymer enhanced layer is made by PET, PI, or epoxy resin.

10. A flexible display panel, comprising:
a TFT layer, a display layer, an encapsulation layer and a flexible glass substrate; and
wherein a polymer enhanced layer is formed at one side of the flexible glass substrate, and the TFT layer is arranged at the other side of the flexible glass substrate opposite to the polymer enhanced layer, the display layer is arranged on the TFT layer, and an encapsulation layer is arranged on the side of the flexible glass substrate where the TFT layer is located.

11. The flexible display panel as claimed in claim 10, wherein the polymer enhanced layer is made by PET, PI, or epoxy resin.

12. The flexible glass substrate as claimed in claim 11, wherein the display layer is an OLED layer.

13. The flexible glass substrate as claimed in claim 12, wherein the OLED layer comprises an anode metal layer, an organic layer and a cathode metal layer, the OLED layer is formed by ink-jet printing or vacuum evaporation, and the OLED layer is formed by a surface film formation or a roll-to-roll process.
